(19) United States
(12) Patent Application Publication
(10) Pub. No.: US 2021/0335760 A1
(43) Pub. Date: Oct. 28, 2021

(54) LED BRACKET, LED DEVICE, AND EDGE-LIT BACKLIGHT MODULE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Yuexia LIN, Shenzhen, Guangdong (CN); Chong XIONG, Shenzhen, Guangdong (CN)

(21) Appl. No.: 16/492,412

(22) PCT Filed: Mar. 25, 2019
(86) PCT No.: PCT/CN2019/079440

§ 371 Date: Sep. 9, 2019

(30) Foreign Application Priority Data
Mar. 7, 2019 (CN) 201910173512.0

(51) Int. Cl. H01L 25/075; H01L 33/62; F21V 8/00

(52) U.S. Cl. CPC H01L 25/0753; H01L 33/62; H01L 24/45; G02B 6/0068; G02B 6/0073

(57) ABSTRACT

The present invention provides a light emitting diode (LED) bracket, an LED device, and an edge-lit backlight module. The LED bracket includes an insulating stand, and a conductive anode lead and a conductive cathode lead which are embedded in the insulating stand. The conductive anode lead and the conductive cathode lead comprise an anode pad and a cathode pad exposed from an upper surface of the insulating stand. The anode pad and the cathode pad are arranged symmetrical to each other on the insulating stand. The present invention utilizes symmetrically arranged metal pads to effectively solve a color difference problem of the LED device, improve luminous efficiency and stability of the LED device, and realize large-sized chip packaging, high-efficiency flip-chip packaging, and high-voltage LED packaging.

### 1. FIELD OF DISCLOSURE

The present invention relates to a field of display devices and in particular, to a light emitting diode (LED) bracket, an LED device, and an edge-lit backlight module.

### 2. DESCRIPTION OF RELATED ART

In recent years, liquid crystal displays (LCDs) have become the mainstream of current displays because they can truly present real colors in nature. Most of the LCD devices on the market are backlight type LCD devices, including liquid crystal panels and backlight modules. Generally, a structure of a liquid crystal panel is constituted by a color filter (CF) substrate, a thin film transistor (TFT) array substrate, and a liquid crystal layer disposed between the two substrates. The operation principle of the liquid crystal panel is to control rotation of liquid crystal molecules of the liquid crystal layer by applying a driving voltage on the two glass substrates, and refract light from the backlight module to generate a picture.

Since the liquid crystal panel itself does not emit light, a light source provided by the backlight module is required to display an image normally. Therefore, the backlight module becomes one of key components of the liquid crystal display device. The backlight modules used in the current LCDs can be roughly categorized into a direct-lit backlight module and an edge-lit backlight module according to different light incident modes. The direct-lit backlight module is configured such that a light source such as a cold cathode fluorescent lamp (CCFL) or a light emitting diode (LED) is disposed behind the liquid crystal panel, so the design and wiring are complicated and troublesome, more light sources are used, and the production costs are high. By contrast, the edge-lit backlight module has an LED light bar on an edge of a back plate and collaborates with a light guide plate. Light emitted from the LED light bar enters the light guide plate through a light-incident surface on one side of the light guide plate, and the light is reflected and diffused and then emitted from a light emitting surface of the light guide plate to form a surface light source for the liquid crystal panel. The edge-lit backlight module has been widely used in portable display devices and become the mainstream because of its low costs, low power consumption, and environmental protection.

As LED backlights are widely used in medium and large size backlight modules, LED devices have higher demands for LED backlights on luminous intensity, luminous uniformity, and reliability. The LED device mainly comprises an LED bracket, an LED chip mounted on the LED bracket, and a fluorescent adhesive containing phosphor powder and covering the LED chip. FIG. 1 is a schematic view of an LED bracket in a conventional edge-lit backlight module, the bracket includes white plastic 1 and two conductive anode and cathode leads embedded in the white plastic 1. Two metal pads of the two conductive leads are exposed from an upper surface of the white plastic 1. The two metal pads show an asymmetric design which includes one large pad 2 and one small pad 3. As shown in FIG. 2, an LED chip 50 is placed on the large pad 2, thus causing blue light intensity above the large pad 2 to be larger than blue light intensity above the small pad 2. After the phosphor powder is applied, blue light excites the phosphor powder to generate yellow light, and the blue light and yellow light are mixed to form a white light. Since the blue light intensity above the small pad 3 is small, blue light cannot be sufficiently mixed with yellow light to form white light, thereby causing a yellowish output light, that is, there is a color difference in the output light of the LED device. In addition, the LED chip 50 is placed on the large pad 2, so a size of the LED chip 50 is limited by a size of the large pad 2. However, the small pad 3 fails to be fully utilized in die bonding, so a larger LED chip cannot be accommodated.

### SUMMARY

It is an objective of the present invention to provide a light emitting diode (LED) bracket which utilizes symmetrically arranged metal pads to solve a color difference problem of an LED device, improve stability of the LED device, and realize large-sized chip packaging, high-efficiency flip-chip packaging, and high-voltage LED packaging.

It is another objective of the present invention to provide an LED device having the above-mentioned LED bracket, so that a color difference problem of the LED device is effectively solved, and stability of the LED device is improved.

It is still another objective of the present invention to provide an edge-lit backlight module having the above-mentioned LED device, so that a color difference problem of the LED device is effectively solved, and stability of the LED device is improved.

Accordingly, the present invention provides a light emitting diode (LED) bracket, comprising:

an insulating stand; and

a conductive anode lead and a conductive cathode lead which are embedded in the insulating stand;

wherein the conductive anode lead comprises an anode pad exposed from an upper surface of the insulating stand, the conductive cathode lead comprises a cathode pad exposed from the upper surface of the insulating stand, and the anode pad and the cathode pad are arranged symmetrical to each other on the insulating stand.

The insulating stand is made of white plastic.

The insulating stand is of a rectangular shape, and the anode pad and the cathode pad are arranged symmetrical to each other in a lengthwise direction of the insulating stand.

The insulating stand is of a rectangular shape, and the anode pad and the cathode pad are arranged symmetrical to each other in a widthwise direction of the insulating stand.

The insulating stand comprises a spacer and an insulating base, the spacer is disposed between the anode pad and the cathode pad, the insulating base is connected to the spacer, and the insulating base defines an accommodating chamber over the anode pad, the cathode pad, and the spacer.

A light emitting diode (LED) device, comprising:

an LED bracket; and

two or more LED chips symmetrically mounted on the LED bracket.

Each of the LED chips is a flip-chip LED chip, and two electrodes of each flip-chip LED chip are electrically connected to the anode pad and the cathode pad in a direct manner, respectively.

Each of the LED chips is a wire-bonded LED chip, and two electrodes of each wire-bonded LED chip are respectively electrically connected to the anode pad and the cathode pad by a plurality of gold wires.

The LED device further comprises a fluorescent adhesive which covers each of the LED chips.

The present invention provides an edge-lit backlight module, comprising:

a light guide plate; and

a light emitting diode (LED) light source disposed on a light incident side of the light guide plate;

wherein the LED light source comprises an elongated base and a plurality of the above-mentioned LED devices disposed on the elongated base.

Advantages of the present invention: The LED bracket of the present invention comprises an insulating stand, and a conductive anode lead and a conductive cathode lead which are embedded in the insulating stand. The conductive anode lead and the conductive cathode lead comprise an anode pad and a cathode pad exposed from an upper surface of the insulating stand, respectively. The anode pad and the cathode pad are symmetrically arranged on the insulating stand. The present invention utilizes the symmetrically arranged metal pads to effectively solve a color difference problem of the LED device, improve luminous efficiency and stability of the LED device, and realize large-sized chip packaging, high-efficiency flip-chip packaging, and high-voltage LED packaging. The LED device of the present invention utilizes the above LED bracket, thus effectively solving the color difference problem of the LED device, and improving luminous efficiency and stability of the LED device. The edge-lit backlight module of the present invention utilizes the above LED device, thereby effectively solving the color difference problem of the LED device, and improving luminous efficiency and stability of the LED device.

### BRIEF DESCRIPTION OF DRAWINGS

In order to further understand the features and technical contents of the present invention, a detailed description of the invention is provided with reference to the accompanying drawings. However, the accompanying drawings are illustrative only and not intended to limit the invention. In the drawings:

FIG. 1 is a schematic structural view illustrating a conventional light emitting diode (LED) bracket;

FIG. 2 is a schematic structural view illustrating a conventional LED device;

FIG. 3 is a schematic view illustrating an LED bracket of the present invention, wherein an anode pad and a cathode pad are arranged symmetrical to each other in a lengthwise direction of an insulating stand;

FIG. 4 is a schematic view illustrating the LED bracket of the present invention, wherein the anode pad and the cathode pad are arranged symmetrical to each other in the lengthwise direction of the insulating stand;

FIG. 5 is a schematic view illustrating that the LED bracket of the present invention is used to realize large-sized chip packaging;

FIG. 6 is a schematic view illustrating that the LED bracket of the present invention is used to realize high-efficiency flip-chip packaging;

FIG. 7 is a schematic view illustrating that the LED bracket is used to realize high-voltage LED packaging; and

FIG. 8 is a schematic top structure view illustrating that the present invention is used in an edge-lit backlight module.

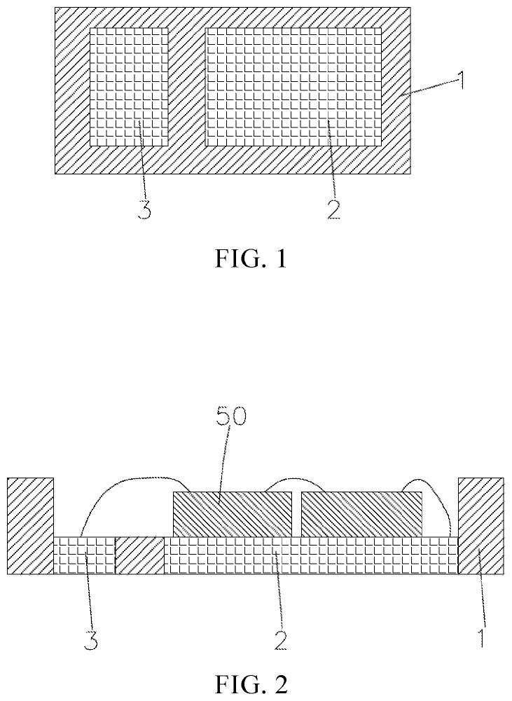

### DETAILED DESCRIPTION OF EMBODIMENTS

In order to further clarify the technical means and functions of the present invention, embodiments of the present invention are described in detail with reference to the accompanying drawings as follows.

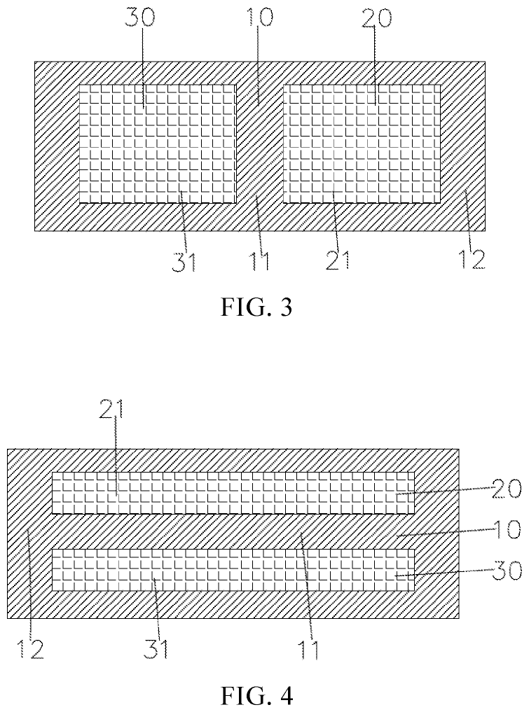

Referring to FIGS. 3 and 4, the present invention provides a light emitting diode (LED) bracket. The LED bracket comprises an insulating stand 10 and comprises a conductive anode lead 20 and a conductive cathode lead 30 which are embedded in the insulating stand 10.

The conductive anode lead 20 comprises an anode pad 21 exposed from an upper surface of the insulating stand 10 and an anode metal terminal (not illustrated) connected to the anode pad 21 and extended out from the insulating stand 10.

The conductive cathode lead 30 comprises a cathode pad 31 exposed from the upper surface of the insulating stand 10 and a cathode metal terminal (not illustrated) connected to the cathode pad 31 and extended out from the insulating stand 10.

The insulating stand 10 comprises a spacer 11 and an insulating base 12, wherein the spacer 11 is disposed between the anode pad 21 and the cathode pad 31, the insulating base 12 is connected to the spacer 11, and the insulating base 12 defines an accommodating chamber 15 over the anode pad 21, the cathode pad 31, and the spacer 11. The accommodating chamber 15 is used to accommodate LED chips and a fluorescent adhesive.

The anode pad 21 and the cathode pad 31 are arranged symmetrical to each other at two sides of the spacer 11 on the insulating stand 10.

In detail, the insulating stand 10 is made of white plastic.

Specifically, the insulating stand 10 is of a rectangular shape having two opposite short sides and two opposite long sides connected to the two short sides.

Referring to FIG. 3, in detail, the anode pad 21 and the cathode pad 31 are arranged symmetrical to each other in a lengthwise direction of the insulating stand 10. The spacer 11 is parallel to the short sides of the insulating stand 10.

Furthermore, referring to FIG. 4, the anode pad 21 and the cathode pad 31 are arranged symmetrical to each other in a widthwise direction of the insulating stand 10. The spacer 11 is parallel to the long sides of the insulating stand 10.

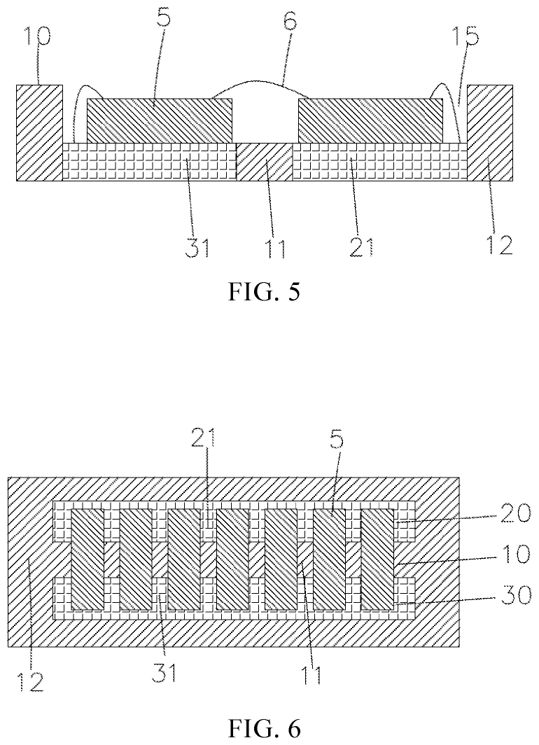

Moreover, the LED bracket of the present invention is used in an LED device, and can be used to realize a large-sized chip package. Specifically, as shown in FIG. 5, the anode pad 21 and the cathode pad 31 are arranged symmetrical to each other in the lengthwise direction of the insulating stand 10, and two LED chips 5 are respectively placed on the anode pad 21 and the cathode pad 31, so that the entire LED device emits light symmetrically, and after the fluorescent adhesive is encapsulated on the LED chips 5, uniform light mixing is achieved, so a color difference problem of a conventional LED device can be improved. The LED bracket of FIG. 4 is a 4014 LED bracket, and the two LED chips 5 are arranged symmetrical to each other on the insulating stand 10. In a conventional LED device shown in FIG. 2, both LED chips of the conventional LED device are mounted on a larger pad of a common 4014 LED bracket. In comparison, an effective pad area for mounting the LED chips 5 in the present invention is the sum of areas of the anode pad 21 and the cathode pad 31, but the effective pad area for mounting the LED chips in a conventional LED bracket is limited to an area of the larger pad. In contrast, the LED bracket of the present invention can fully use the areas of the anode pad 21 and the cathode pad 31 to realize a large-sized chip package, thereby increasing luminous intensity of a single LED.

Specifically, the LED bracket of the present invention is used in an LED device, and can also be used to realize high-efficiency flip-chip packaging. As shown in FIG. 6, in details, the anode pad 21 and the cathode pad 31 are arranged symmetrical to each other in the widthwise direction of the insulating stand 10, and two or more LED chips 5 which are flip-chip LED chips are directly bonded on the anode pad 21 and the cathode pad 31 by a conductive silver paste. Two electrodes of each of the flip-chip LED chips are electrically connected to the anode pad 21 and the cathode pad 31 in a direct manner, respectively. In the LED device shown in FIG. 5, a plurality of flip-chip LED chips are symmetrically arranged on the anode pad 21 and the cathode pad 31, so the LED device emits light symmetrically and uniformly, which improving a color difference problem of the conventional LED device. Since multiple small-sized chips are used instead of two large-sized chips, each single LED chip 5 has reduced electrical power when an output electrical power is maintained the same. As a result, operating temperatures are decreased, luminous efficiency and reliability of the LED chip 5 are improved, and thereby performance of the LED device is also improved.

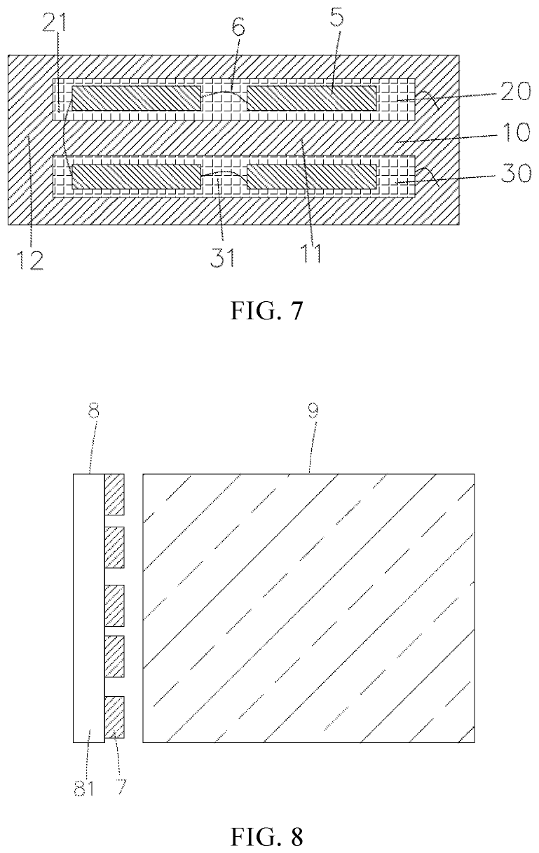

Specifically, when the LED bracket of the present invention is used in the LED device, it can also be used to realize high-voltage LED packaging. Specifically, referring to FIG. 7, the anode pad 21 and the cathode pad 31 are arranged symmetrical to each other in the widthwise direction of the insulating stand 10. Multiple wire-bonded LED chips 5 are bonded in series on the anode pad 21 and the cathode pad 31 through gold wires 6, so that light are emitted uniformly and symmetrically, and a color different problem of the conventional LED device is improved. Since multiple small-sized wire-bonded LED chips 5 are used at the same time, a current is low and a voltage is high when an electrical output power is maintained the same, thus enabling high-voltage LED packaging which can be used in high dynamic range imaging (HDR) product designs.

The LED bracket of the present invention adopts symmetrically arranged metal pads, thereby effectively solving a color difference problem of a conventional LED device, improving luminous efficiency and stability of the LED device, and realizing large-sized chip packaging, high-efficiency flip-chip packaging, and high-voltage LED packaging.

The present invention also provides an LED device based on the above LED bracket. Referring to FIG. 5, the LED device according to the first embodiment of the present invention comprises the LED bracket as described above, two LED chips 5 mounted on the LED bracket, and a fluorescent adhesive (not illustrated) filled in the accommodating chamber 15 and covering the LED chips 5.

Specifically, in the present embodiment, the anode pad 21 and the cathode pad 31 of the LED bracket are arranged symmetrical to each other in the lengthwise direction of the insulating stand 10, and the two LED chips 5 are respectively placed on the anode pad 21 and the cathode pad 31. The two LED chips 5 are connected in series by a plurality of gold wires 6. The other technical features of the LED bracket are the same as those of the LED bracket of the above-mentioned embodiments, so are not described again for brevity.

Referring to FIG. 6, the LED device of the second embodiment is different from the LED device of the first embodiment of the present invention in that, the anode pad 21 and the cathode pad 31 of the LED bracket are arranged symmetrical to each other in the widthwise direction of the insulating stand 10. The LED chips 5 are two flip-chip LED chips or more, and the two electrodes of each of flip-chip LED chips are electrically connected in a direct manner to the anode pad 21 and the cathode pad 31, respectively. The multiple flip-chip LED chips are symmetrically arranged on the anode pad 21 and the cathode pad 31, so light can be emitted uniformly and symmetrically, thus solving the color difference problem of the conventional LED device. Furthermore, since multiple small-sized LED chips are used instead of two large-sized LED chips, each single LED chip 5 has reduced electrical power when an output electrical power is maintained the same. As a result, operating temperatures are lowered, which is beneficial to improving luminous efficiency and reliability of the LED chips 5, thereby improving performance of the LED device. Other technical features are the same as those of the LED device of the first embodiment described above, and hence are not described again for brevity.

Referring to FIG. 7, the LED device of the third embodiment is different from the LED device of the second embodiment of the present invention in that, the LED chips 5 are wire-bonded LED chips, and the multiple wire-bonded LED chips 5 are symmetrically arranged on the anode pad 21 and the cathode pad 31 and are connected in series via gold wires 6. Other technical features are the same as those of the LED device of the second embodiment described above, and hence are not described again for brevity.

In the LED bracket of the LED device of the present invention, the anode pad 21 and the cathode pad 31 are symmetrically arranged on the insulating stand 10, thus effectively solving the color difference problem of the LED device and improving the luminous efficiency and stability of the LED device.

Referring to FIG. 8, on the basis of the LED device mentioned above, the present invention further provides a backlight module which comprises a light guide plate 9 and an LED light source 8 disposed on a light incident side of the light guide plate 9.

The LED light source 8 comprises an elongated base 81 and a plurality of LED devices 7 arranged juxtaposed and disposed on the elongated base 81. Each LED device 7 comprises the LED bracket mentioned above, two or more LED chips 5 mounted on the LED bracket, and a fluorescent adhesive filled in the accommodating chamber 15 and covering the LED chips 5. The LED chips 5 are symmetrically arranged on the LED bracket. The technical features of the LED bracket are the same as those of the LED bracket mentioned above, so are not described again for brevity.

In the backlight module of the present invention, the anode pad 21 and the cathode pad 31 are symmetrically arranged on the insulating stand 10 in the LED bracket, thus effectively solving the color difference problem of the LED device and improving the luminous efficiency and stability of the LED device.

In summary, the LED bracket provided by the present invention comprises an insulating stand and comprises a conductive anode lead and a conductive cathode lead embedded in the insulating stand. The conductive anode lead and the conductive cathode lead comprise an anode pad and a cathode pad exposed from an upper surface of the insulating stand, and the anode pad and the cathode pad are arranged symmetrical to each other on the insulating stand. The present invention utilizes symmetrically arranged metal pads to effectively solve the color difference problem of the LED device, improve the luminous efficiency and stability of the LED device, and realize large-sized chip packaging, high-efficiency flip-chip packaging, and high-voltage LED packaging. The LED device of the present invention utilizes the above LED bracket, thereby effectively solving the color difference problem of the LED device, and improving the luminous efficiency and stability of the LED device. The edge-lit backlight module of the present invention adopts the above LED device, thus effectively solving the color difference problem of the LED device, and improving the luminous efficiency and stability of the LED device.

It is to be understood that the above descriptions are merely the preferable embodiments of the present invention and are not intended to limit the scope of the present invention. Equivalent changes and modifications made in the spirit of the present invention are regarded as falling within the scope of the present invention.

What is claimed is:

1. A light emitting diode (LED) bracket, comprising:
an insulating stand; and
a conductive anode lead and a conductive cathode lead which are embedded in the insulating stand;
wherein the conductive anode lead comprises an anode pad exposed from an upper surface of the insulating stand, the conductive cathode lead comprises a cathode pad exposed from the upper surface of the insulating stand, and the anode pad and the cathode pad are arranged symmetrical to each other on the insulating stand.

2. The LED bracket according to claim 1, wherein the insulating stand is made of white plastic.

3. The LED bracket according to claim 1, wherein the insulating stand is of a rectangular shape, and the anode pad and the cathode pad are arranged symmetrical to each other in a lengthwise direction of the insulating stand.

4. The LED bracket according to claim 1, wherein the insulating stand is of a rectangular shape, and the anode pad and the cathode pad are arranged symmetrical to each other in a widthwise direction of the insulating stand.

5. The LED bracket according to claim 1, wherein the insulating stand comprises a spacer and an insulating base, the spacer is disposed between the anode pad and the cathode pad, the insulating base is connected to the spacer, and the insulating base defines an accommodating chamber over the anode pad, the cathode pad, and the spacer.

6. A light emitting diode (LED) device, comprising:
an LED bracket; and
two or more LED chips symmetrically mounted on the LED bracket;
wherein the LED bracket comprises:
an insulating stand; and
a conductive anode lead and a conductive cathode lead which are embedded in the insulating stand;
wherein the conductive anode lead comprises an anode pad exposed from an upper surface of the insulating stand, the conductive cathode lead comprises a cathode pad exposed from the upper surface of the insulating stand, and the anode pad and the cathode pad are arranged symmetrical to each other on the insulation stand.

7. The LED device according to claim 6, wherein each of the LED chips is a flip-chip LED chip, and two electrodes of each flip-chip LED chip are electrically connected to the anode pad and the cathode pad in a direct manner, respectively.

8. The LED device according to claim 6, wherein each of the LED chips is a wire-bonded LED chip, and two electrodes of each wire-bonded LED chip are respectively electrically connected to the anode pad and the cathode pad by a plurality of gold wires.

9. The LED device according to claim 6, further comprising a fluorescent adhesive which covers each of the LED chips.

10. The LED device according to claim 6, wherein the insulating stand is made of white plastic.

11. The LED device according to claim 6, wherein the insulating stand is of a rectangular shape, and the anode pad and the cathode pad are arranged symmetrical to each other in a lengthwise direction of the insulating stand.

12. The LED device according to claim 6, wherein the insulating stand is of a rectangular shape, and the anode pad and the cathode pad are arranged symmetrical to each other in a widthwise direction of the insulating stand.

13. The LED device according to claim 6, wherein the insulating stand comprises a spacer and an insulating base, the spacer is disposed between the anode pad and the cathode pad, the insulating base is connected to the spacer, and the insulating base defines an accommodating chamber over the anode pad, the cathode pad, and the spacer.

14. An edge-lit backlight module, comprising:
a light guide plate; and
a light emitting diode (LED) light source disposed on a light incident side of the light guide plate;
wherein the LED light source comprises an elongated base and a plurality of LED devices disposed on the elongated base, the LED device comprises:
an LED bracket; and
two or more LED chips symmetrically mounted on the LED bracket;
wherein the LED bracket comprises:
an insulating stand; and
a conductive anode lead and a conductive cathode lead which are embedded in the insulating stand;
wherein the conductive anode lead comprises an anode pad exposed from an upper surface of the insulating stand, the conductive cathode lead comprises a cathode pad exposed from the upper surface of the insulating stand, and the anode pad and the cathode pad are arranged symmetrical to each other on the insulating stand.

15. The edge-lit backlight module according to claim 14, wherein each of the LED chips is a flip-chip LED chip, and two electrodes of each flip-chip LED chip are electrically connected to the anode pad and the cathode pad in a direct manner, respectively.

16. The edge-lit backlight module according to claim 14, wherein each of the LED chips is a wire-bonded LED chip, and two electrodes of each wire-bonded LED chip are respectively electrically connected to the anode pad and the cathode pad by a plurality of gold wires.

17. The edge-lit backlight module according to claim 14, wherein each of the LED device further comprises a fluorescent adhesive which covers each of the LED chips.

18. The edge-lit backlight module according to claim 14, wherein the insulating stand is made of white plastic.

19. The edge-lit backlight module according to claim 14, wherein the insulating stand is of a rectangular shape, and the anode pad and the cathode pad are arranged symmetrical to each other in a lengthwise or widthwise direction of the insulating stand.

20. The edge-lit backlight module according to claim 14, wherein the insulating stand comprises a spacer and an insulating base, the spacer is disposed between the anode pad and the cathode pad, the insulating base is connected to the spacer, and the insulating base defines an accommodating chamber over the anode pad, the cathode pad, and the spacer.
